(19) United States
(12) Patent Application Publication
(10) Pub. No.: US 2023/0028006 A1
(43) Pub. Date: Jan. 26, 2023

(54) PHOTORESIST COMPOSITION AND METHODS OF USE

(71) Applicant: Taiwan Semiconductor Manufacturing Co., Ltd., Hsinchu (TW)

(72) Inventors: Yen-Hao CHEN, Hsinchu (TW); Wei-Han LAI, Hsinchu (TW); Ching-Yu CHANG, Hsinchu (TW)

(21) Appl. No.: 17/737,810

(22) Filed: May 5, 2022

Related U.S. Application Data
(60) Provisional application No. 63/215,319, filed on Jun. 25, 2021.

(51) Int. Cl. G03F 7/004; G03F 7/16; H01L 21/027

(52) U.S. Cl. CPC G03F 7/0045; G03F 7/168; G03F 7/0048; H01L 21/0274

(57) ABSTRACT

Novel photoresist additive compositions including developer solubility groups which enhance the solubility of the photoresist additive in a developer, such as a TMAH developer. The novel photoresist additive compositions also include functional groups to address outgassing and out-of-band issues.

### BACKGROUND

The semiconductor industry has experienced exponential growth. Technological advances in materials and design have produced generations of integrated circuits (ICs), where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs.

In one exemplary aspect, photolithography is a process used in semiconductor micro-fabrication to selectively remove parts of a thin film or a substrate. The process uses light to transfer a pattern (e.g., a geometric pattern) from a photomask to a light-sensitive layer (e.g., a photoresist layer) on the substrate. The light causes a chemical change (e.g., increasing or decreasing solubility) in exposed regions of the light-sensitive layer. Baking processes may be performed before and/or after exposing the substrate, such as in a pre-exposure and/or a post-exposure baking process. A developing process then selectively removes the exposed or unexposed regions with a developer solution forming an exposure pattern in the substrate. Finally, a process is implemented to remove (or strip) the remaining photoresist from the underlying material layer(s), which may be subjected to additional circuit fabrication steps. For a complex IC device, a substrate may undergo multiple photolithographic patterning processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor device at an intermediate stage of fabrication in accordance with an embodiment of the present disclosure.

FIG. 2 is a chemical formula of a photoresist additive in accordance with an embodiment of the present disclosure.

FIGS. 3-8 are chemical formulas of example photoresist additives in accordance with multiple embodiments of the present disclosure.

FIG. 9 is a cross-sectional view of a semiconductor device at an intermediate stage of fabrication in accordance with an embodiment of the present disclosure.

FIG. 10 is a cross-sectional view of a semiconductor device at an intermediate stage of fabrication in accordance with an embodiment of the present disclosure.

FIG. 11 is a flowchart of a method in accordance with an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

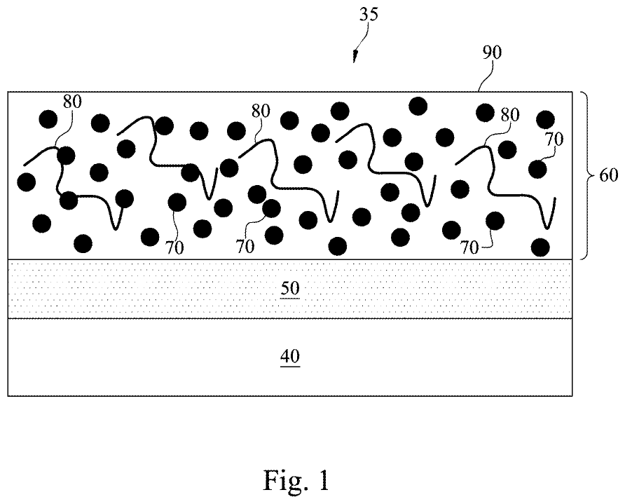

FIGS. 1, 9, and 10 are diagrammatic fragmentary cross-sectional side views of a semiconductor device 35 at various stages of fabrication in accordance with various aspects of the present disclosure. The semiconductor device 35 may include an integrated circuit (IC) chip, system on chip (SoC), or portion thereof, and may include various passive and active microelectronic devices such as resistors, capacitors, inductors, diodes, metal-oxide semiconductor field effect transistors (MOSFET, for example, in the form of planar FETs, finFETs and nanosheet FETs), complementary metal-oxide semiconductor (CMOS) transistors, bipolar junction transistors (BJT), laterally diffused MOS (LDMOS) transistors, high power MOS transistors, or other types of transistors.

Extreme ultraviolet (EUV) lithography has become widely used due to its ability to achieve small semiconductor device sizes, for example, for 20 nanometer (nm) technology nodes or smaller. However, challenges remain with EUV lithography. For example, photoresist outgassing and effects of out of band (OOB) radiation remain a challenge for EUV lithography. In more detail, during (or after) an exposure process in EUV lithography, a photoresist material coated on a semiconductor wafer may produce outgassing products or species. When allowed to escape from the photoresist, the outgassing products may contaminate lithography tools and degrade lithography performance. Among other things, these outgassing products may be produced from the photo acid generator (PAG), photochemical cleavage of protecting groups, or decomposition products from the photo acid generator. As non-limiting examples, the PAG may outgas tertbutylbenzene during acid generation, and the polymer in the photoresist may outgas isobutene during the deprotection reaction. OOB radiation can negatively impact the image precision during an exposure process applied to the photoresist.

To suppress the photoresist outgassing products and/or the negative effect of the OOB radiation, a protective layer has been proposed to be formed over the photoresist surface. In this manner, the outgassing products can be blocked by the protective layer, thereby reducing the emission of the photoresist outgassing products. The protective layer can absorb OOB wavelengths. This approach, while effective, can incur higher fabrication costs (i.e., due to the extra material for the protective layer and the additional tools used to form it), but it may also negatively impact lithography performance, as it can effectively increase the photoresist “height”, thereby causing issues related to smaller process window, weak collapse margin, poor depth of focus, or resist film loss.

In addition, solubility of the exposed photoresist in the developer solution, e.g., a TMAH solution, remains a challenge. Insufficient solubility of the photoresist in the developer solution can result in unsatisfactory pattern transfer to the workpiece. In addition, the LWR and LCDU are negatively impacted when the photoresist has unsatisfactory solubility in the developer solution. The drawbacks of such challenges are exacerbated with decreasing feature sizes.

The present disclosure provides a novel approach to address the photoresist solubility challenge as well as other challenges. For example, some embodiments of the present disclosure help to address the photoresist outgassing and OOB radiation challenges as well. Some embodiments of the present disclosure do not suffer from the drawbacks discussed above regarding increasing the height of the photoresist, such as encountered with a protective top coating approach. The various aspects of the present disclosure will be discussed below in greater detail with reference to FIGS. 1-11.

Referring to FIG. 1, a semiconductor device 35 includes a substrate 40. In some embodiments, the substrate 40 is a silicon substrate. In other embodiments, the substrate 40 is a silicon substrate doped with a p-type dopant such as boron (for example a p-type substrate). Alternatively, the substrate 40 could be another suitable semiconductor material. For example, the substrate 40 may be a silicon substrate that is doped with an n-type dopant such as phosphorous or arsenic (an n-type substrate). The substrate 40 could include other elementary semiconductors such as germanium and diamond. The substrate 40 could optionally include a compound semiconductor and/or an alloy semiconductor. Further, the substrate 40 could include an epitaxial layer (epi layer), may be strained for performance enhancement, and may include a silicon-on-insulator (SOI) structure.

In some embodiments, the substrate 40 is substantially conductive or semi-conductive. The electrical resistance may be less than about 10³ ohm-meter. In some embodiments, the substrate 40 contains metal, metal alloy, or metal nitride/sulfide/selenide/oxide/silicide with the formula MXₐ, where M is a metal, and X is N, S, Se, O, Si, and where “a” is in a range from about 0.4 to 2.5. For example, the substrate 40 may contain Ti, Al, Co, Ru, TiN, WN₂, or TaN.

In some other embodiments, the substrate 40 contains a dielectric material with a dielectric constant in a range from about 1 to about 40. In some other embodiments, the substrate 40 contains Si, metal oxide, or metal nitride, where the formula is MX_{b}, wherein M is a metal or Si, and X is N or O, and wherein “b” is in a range from about 0.4 to 2.5. For example, the substrate 40 may contain SiO₂, silicon nitride, aluminum oxide, hafnium oxide, or lanthanum oxide.

A material layer 50 is formed over the substrate 40. The material layer 50 can be patterned via a lithography process and, as such, may also be referred to as a patternable layer. In an embodiment, the material layer 50 includes a dielectric material, such as silicon oxide or silicon nitride. In another embodiment, the material layer 50 includes metal. In yet another embodiment, the material layer 50 includes a semiconductor material.

In some embodiments, the material layer 50 has different optical properties than photoresist. For example, the material layer 50 has a different n (index of refraction), k (extinction coefficient), or T_{g} (glass transition temperature) value from photoresist. In some embodiments, the material layer 50 comprises at least one of different polymer structure, acid labile molecule, PAG (photo acid generator) loading, quencher loading, chromophore, cross linker, or solvent, which lead to different n value relative to photoresist. In some embodiments, the material layer 50 and photoresist have different etching resistance. In some embodiments, the material layer 50 contains an etching resistant molecule. The etching resistant molecule includes an onium salt, double bond, a triple bond, silicon, a silicon nitride, Ti, TiN, Al, aluminum oxide, SiON, or combinations thereof.

It is understood that the substrate 40 and the material layer 50 may each include additional suitable material compositions in other embodiments.

In accordance with an embodiment of the present disclosure, a photoresist material 60 is formed over the material layer 50. In the embodiment shown in FIG. 1, the photoresist material 60 includes a positive photoresist, but it is understood that the photoresist material 60 may be a negative photoresist in alternative embodiments. The photoresist material 60 may be formed by a spin-coating process. The photoresist material 60 contains components such as a polymer, photo acid generators (PAG), quenchers, chromophore, surfactant, cross linker, etc. In an embodiment, the photo acid generator is bonded to the polymer. In a subsequent photolithography process, photons induce decomposition of the PAG. As a result, a small amount of acid is formed, which further induces a cascade of chemical transformations in the photoresist material 60 affecting its solubility in a developing solution. The photoresist material 60 may also optionally include a quencher that is disposed within the photoresist material 60 in order to improve critical dimension (CD) control.

According to the various aspects of the present disclosure, the photoresist material 60 also contains a solvent 70 and an additive 80. The additive 80 may be mixed in the solvent 70. In various embodiments, the solvent 70 may include Propylene Glycol Monomethyl Ether (PGME) or Propylene Glycol Monomethyl Ether Acetate (PGMEA). The additive 80, in accordance with embodiments of the present disclosure, has a low solids content and does not increase the solid contents of the photoresist material 60 by any significant amount when added to the photoresist material 60.

In accordance with some embodiments of the present disclosure, the additive 80 is a polymer containing developer solubility unit or group alone or in combination with one or more of a floating control unit or group, a volume control unit or group and a radiation-absorption control unit or group. The functionalities of the floating control unit or group, volume control unit or group, radiation-absorption control unit or group and developer solubility unit or group and examples of their chemical compositions are discussed in greater detail below.

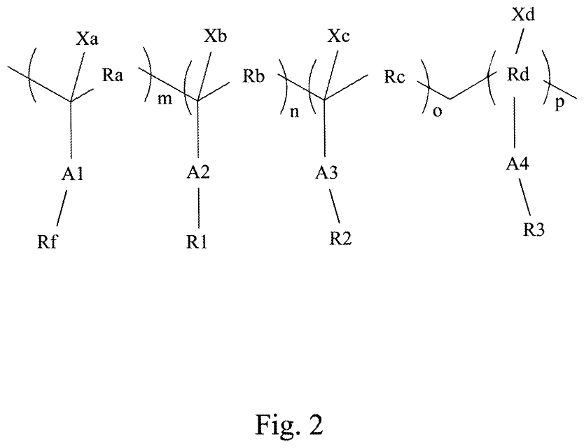

Referring to FIG. 2, the additive 80 has the following chemical formula (or chemical structure) in some embodiments:

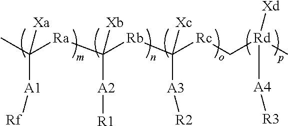

In the embodiment of the additive 80 illustrated above, Rf represents the floating control group, R1 represents the volume control group, R2 represents the radiation-absorption control group and R3 represents the developer solubility group. As previously discussed, embodiments in accordance with the present disclosure are directed to additives that include R3 alone or in combination with one or more of Rf, R1 and R2. In some embodiments, Xa, Xb, Xc and Xd is each independently hydrogen (H), methyl, or fluorine. In other words, Xa may be H, methyl, or fluorine. Likewise, Xb, Xc or Xd may each be H, methyl, or fluorine as well. It is understood that Xa, Xb, Xc or Xd may not necessarily be implemented as the same chemical though. For example, in some embodiments, Xa may be H, Xb may be methyl, Xc may be fluorine and Xd may be H, methyl or fluorine. In other example embodiments, Xa may be methyl, Xb may be methyl, Xc may be H and Xd may be H, methyl or fluorine. In yet other example embodiments, Xa may be H, Xb may be fluorine, Xc may be H and Xd maybe H, methyl or fluorine. Similarly, Ra, Rb, Rc and Rd which represent different segments of the backbone of the additive polymer may independently represent a C0-C7 alkyl group or an aromatic group. In other words, Ra, Rb, Rc and Rd may each be implemented as the C0-C7 alkyl group or as the aromatic group, and Ra, Rb, Rc and Rd need not necessarily be implemented as the same chemical group. In some embodiments, m+n+o+p=1, 0<m<0.8, 0<n<0.8, 0<0<0.5 and 0.1<p<0.8. In some embodiments, A1, A2, A3 and A4 may independently represent a —COO— ester structure or a phenyl-O— (phenoxide) structure.

In accordance with some embodiments of the present disclosure, the solubility control group R3 is a heterocyclic compound or group capable of a ring opening reaction of the cyclic ring, the result of which provides a terminal hydroxyl group (—OH) and a terminal carboxylic acid group (—COOH). Such heterocyclic compound or group includes a cyclic ester group. Such terminal hydroxyl and terminal carboxylic acid groups increase the hydrophilicity of the additive and render it more soluble in developer solutions, such as TMAH. In some embodiments, R3 is a lactone of any membered ring. In some embodiments, lactones of 5-10 membered rings are used. The lactone can be unsubstituted or substituted. One or more hydrogen atoms in the basic lactone structure can be substituted with alkyl groups (e.g., methyl, ethyl, propyl, butyl, etc.), hydroxy groups, alkyloxy groups, cyano group, amino groups, and aromatic groups. Examples of solubility control groups R3 in accordance with the present disclosure have the following chemical formulas:

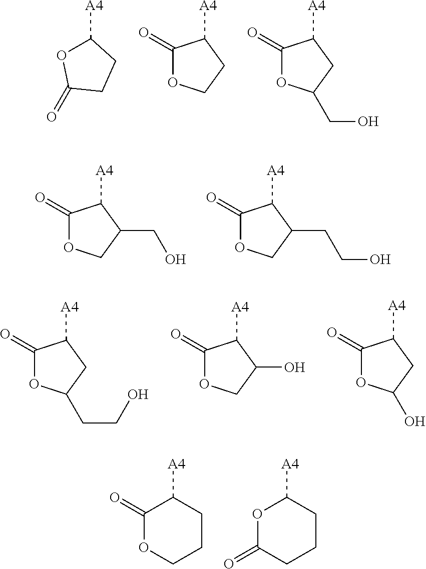

where A4 is —COO— or -phenyl-O. The foregoing solubility control groups when exposed to an environment of greater than pH 9 or pH 10 undergo a ring opening reaction resulting in a functional group having the following chemical formula:

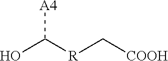

where R is an unbranched or branched, saturated or unsaturated alkyl or alkenyl or alkynyl group. For example, R can be C₁ or C₂ alkyl, however, embodiments in accordance with the present disclosure are not limited to R being C₁ or C₂ alkyl, for example, R can be Cₓ where x is greater than 2.

R3 is not limited to the lactone groups illustrated above, for example, in other embodiments, R3 includes an organic group having a terminal —COOH group, such as an acid group having a —COOH functionality, a thermal acid generator group having a terminal —COOH functional group after a baking process or a photo acid generator group having a terminal —COOH functional group after exposure to patterning light. In other embodiments, R3 is chosen to impart a hydrophobic property to the additive 80 such that the additive 80 has good affinity for the photoresist material 60 prior to the developing process.

The floating control group Rf is configured to cause the additive 80 to float (i.e., rise up) toward an upper surface 90 of the photoresist material 60, particularly as the photoresist material 60 undergoes a spin-drying process or a baking process (which will be performed subsequently as discussed below). The floating control group Rf contains fluorine or a fluorine derivative, for example a C1-C9 fluorine-containing alkyl group. Fluorine reduces surface energy, thereby facilitating the floating of the additive 80 (toward the upper surface 90) within the photoresist material 60. In some embodiments, the ratio (or concentration) of fluorine or fluorine derivative is between about 0% and about 80% in the additive 80. In other words, about 0%-80% of the additive 80 is the fluorine or the fluorine derivative.

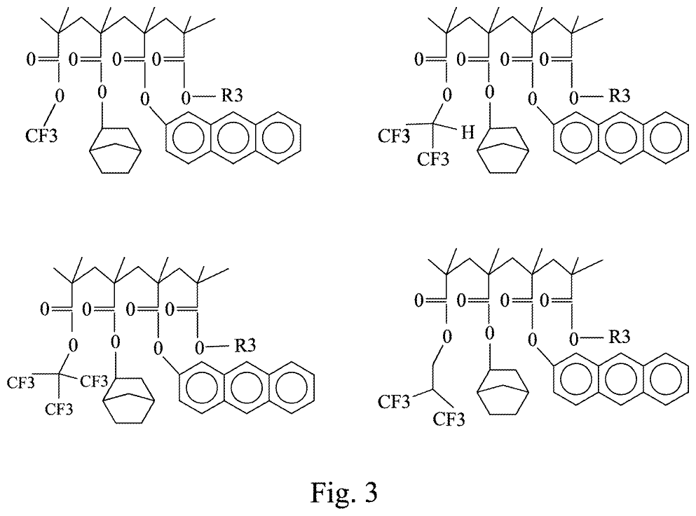

With reference to FIG. 3, an additive in accordance with embodiments of the present disclosure including a developer solubility group R3 in combination with a floating control group Rf, a volume control group R1 and a radiation-absorption control group R2 has one of the following chemical formulas. In the embodiments of FIG. 3, the chemical formula for the volume control group R1 and the radiation-absorption control group R2 are the same. FIG. 3 illustrates different examples of chemical formulas for the floating control group Rf where A1 is an ester group, e.g., —COO— which serves as a link between the Rf group and the backbone of the additive polymer according to some embodiments.

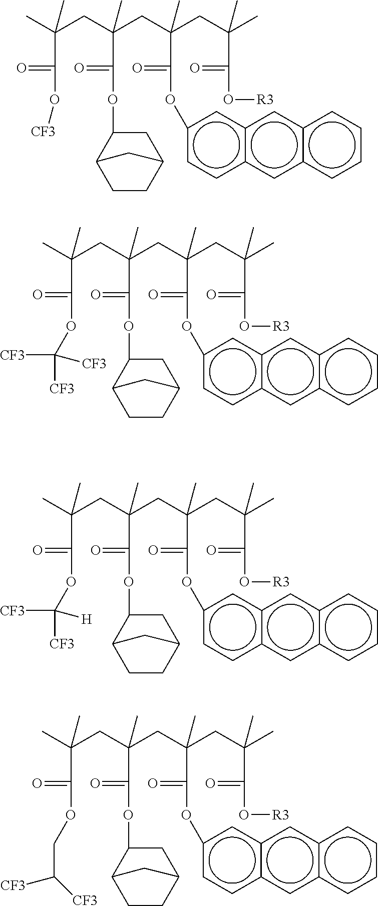

In accordance with some embodiments of the present disclosure, one or more of the fluorine containing alkyl groups (—CF₃) illustrated in the examples of an additive including a floating control group Rf illustrated in FIG. 3, is replaced by an alkyl group that includes fluorine and a hydroxyl group (e.g., —CF₂OH or —CF(OH)₂). In other embodiments, one or more of the fluorine containing alkyl groups is replaced by a hydroxyl group.

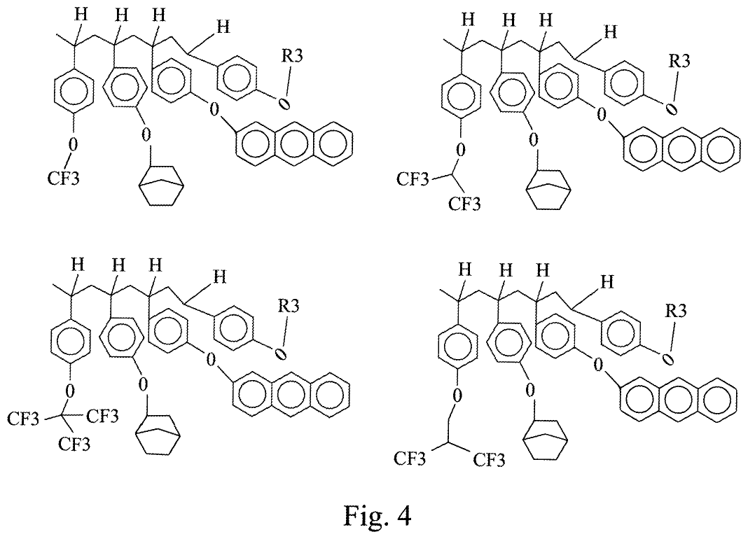

With reference to FIG. 4, in some embodiments, the additive including a developer solubility group R3 in combination with a floating control group Rf, a volume control group R1 and a radiation-absorption control group R2 has one of the following chemical formulas. In the embodiments of FIG. 4, the chemical formula for the volume control group R1 and the radiation-absorption control group R2 are the same. FIG. 4 illustrates different examples of chemical formulas for the floating control group Rf when A1=-Ph-O— (a phenyl oxide group) and provides a link between the floating control group Rf and the backbone of the additive polymer.

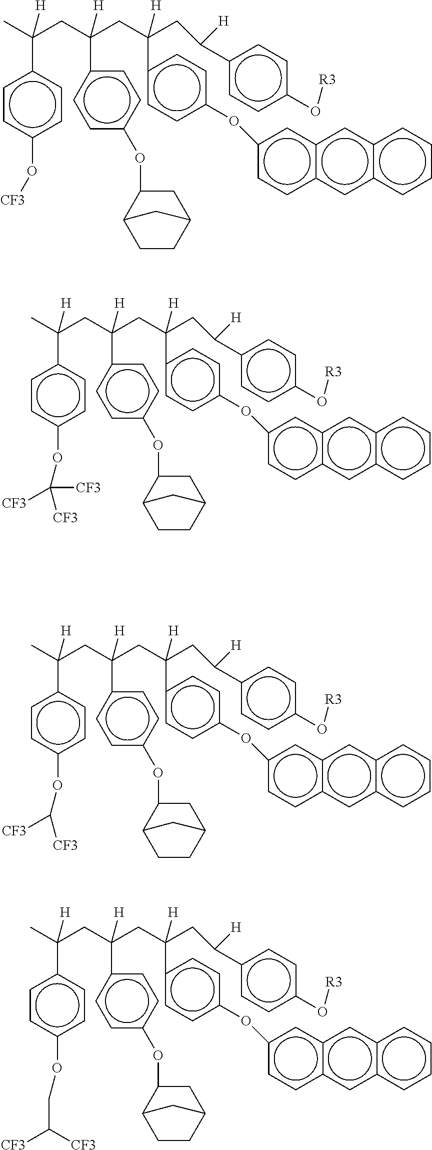

In accordance with some embodiments of the present disclosure, one or more of the fluorine containing alkyl groups (—CF₃) illustrated in the examples of an additive including a floating control group Rf in FIG. 4, is replaced by an alkyl group that includes fluorine and a hydroxyl group (e.g., —CF₂OH or —CF(OH)₂). In other embodiments, one or more of the fluorine containing alkyl groups is replaced by a hydroxyl group.

The volume control group R1 (also referred to as a bulking group) is configured to block photoresist outgassing products described above. In other words, the material composition for the volume control group R1 is sufficiently dense and voluminous such that it serves as a physical barrier for the photoresist outgassing products released during an exposure process (discussed below). Or alternatively stated, due to the presence of the volume control group R1, the photoresist outgassing products cannot penetrate through the additive 80. In some embodiments, the volume control group R1 causes the additive 80 to be denser (i.e., having a greater density) than the rest of the photoresist material 60. In some embodiments, the additive 80 has a molecular weight in a range from about 1000 to about 25000. In some embodiments, the volume control group R1 contains a C5-C20 alkyl group, a cycloalkyl group, a hydroxylalkyl group, an alkoxy group, an alkoxyl alkyl group, an acetyl group, an acetylalkyl group, a carboxyl group, an alky carboxyl group, a cycloalkyl carboxyl group, a C5-C20 saturated or unsaturated hydrocarbon ring, or a C5-C20 heterocyclic group. In some embodiments, the volume control group R1 may include a 2-dimensional ring structure and/or a 3-dimensional crisscross structure. In some embodiments, the ratio (or concentration) of the volume control group R1 is between about 0% and about 50% in the additive 80. In other words, about 0%-50% of the additive 80 is the volume control group R1.

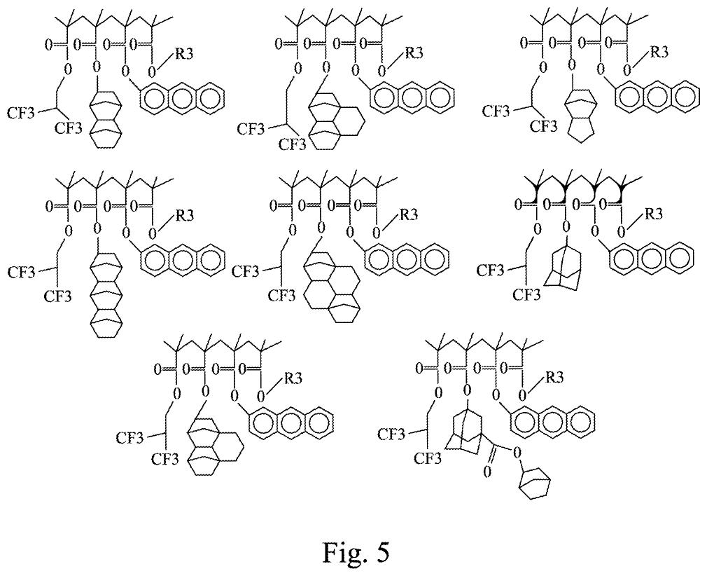

With reference to FIG. 5, in some embodiments, an additive in accordance with embodiments of the present disclosure including a developer solubility group R3 in combination with a floating control group Rf, a volume control group R1 and a radiation-absorption control group R2 has one of the following chemical formulas. In the embodiments of FIG. 5, the chemical formulas for the floating control group Rf and the radiation-absorption control group R2 are the same. FIG. 5 illustrates different examples of chemical formulas for the volume control group R1 where A2 is an ester group, e.g., —COO— which serves as a link between the R1 and the backbone of the additive polymer according to some embodiments.

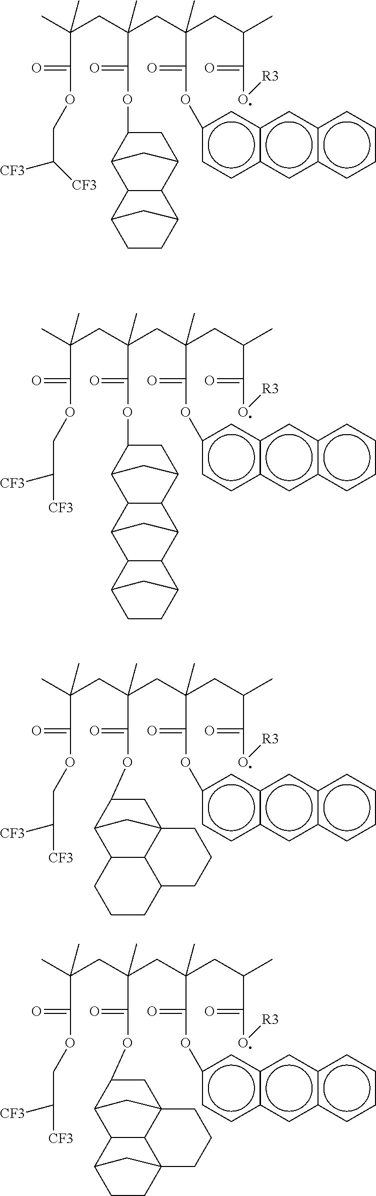

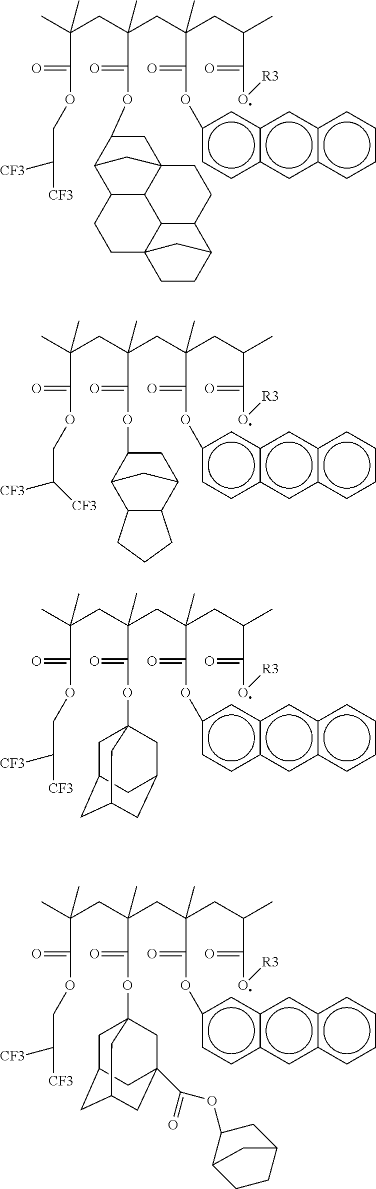

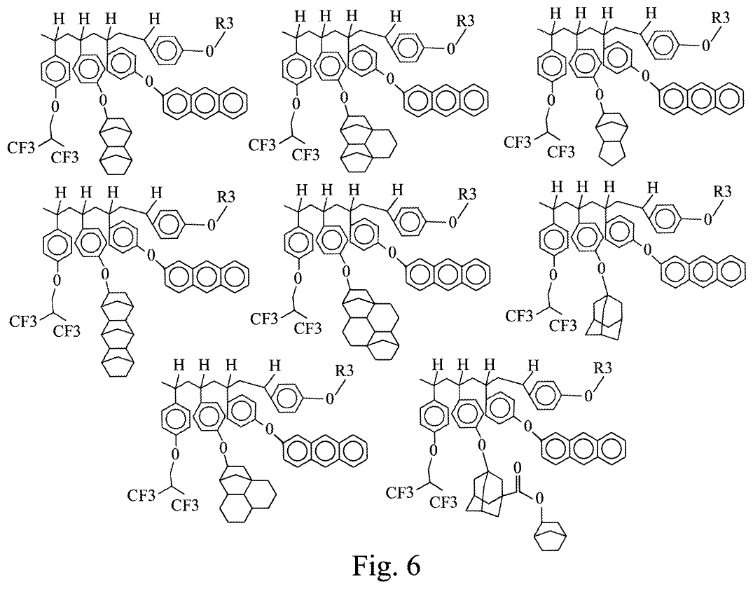

With reference to FIG. 6, in some embodiments, an additive in accordance with embodiments of the present disclosure including a developer solubility group R3 in combination with a floating control group Rf, a volume control group R1 and a radiation-absorption control group R2 has one of the following chemical formulas. In the embodiments of FIG. 6, the chemical formula for the floating control group Rf and the radiation-absorption control group R2 are the same. FIG. 6 illustrates different examples of chemical formulas for the volume control group R1 where A2=PhO— which serves as a link between the R1 and the backbone of the additive polymer.

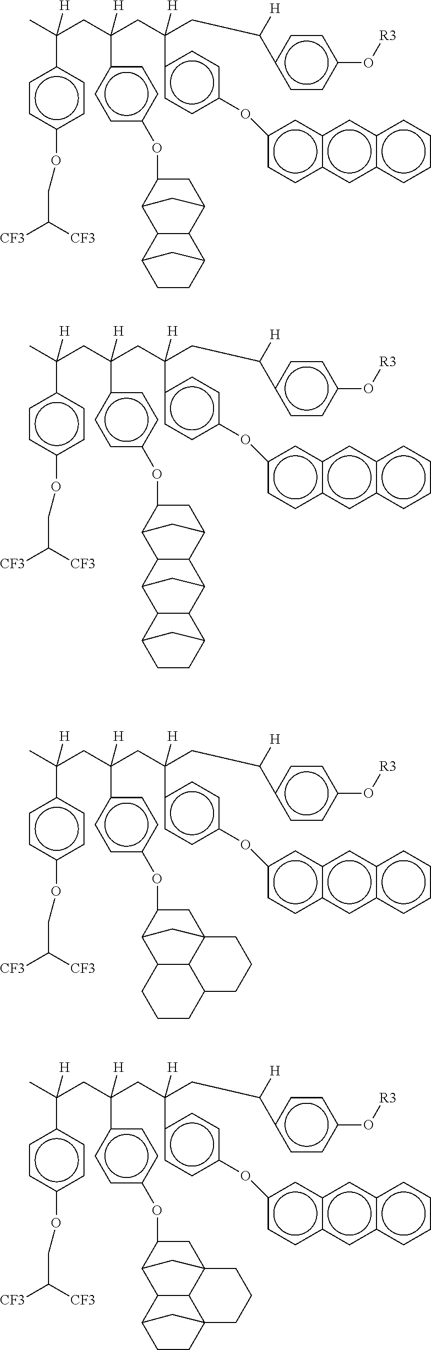

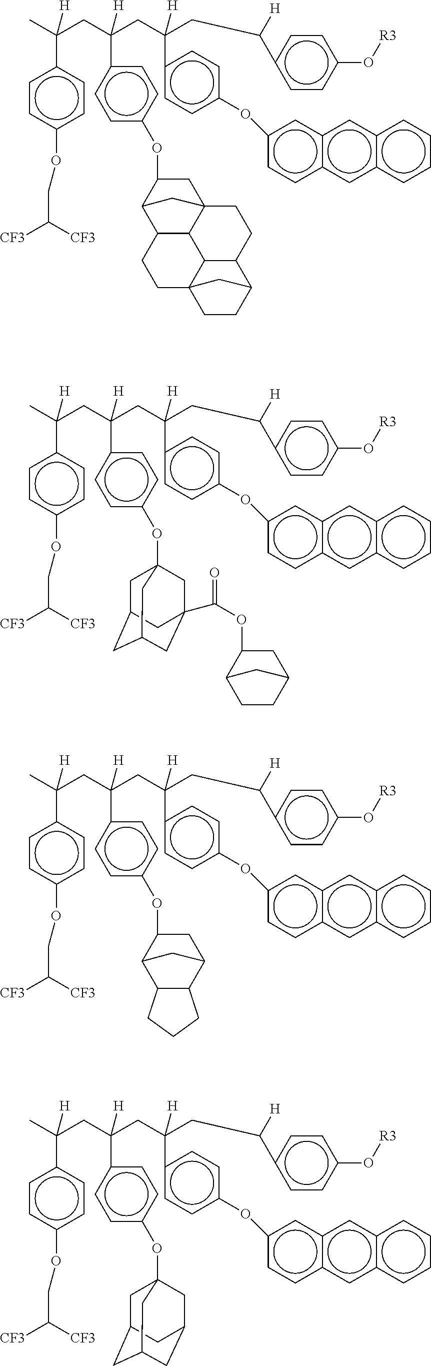

The radiation-absorption control group R2 is configured to absorb out-of-band (OOB) radiation for EUV lithography. For example, the radiation-absorption control group R2 may be configured to absorb radiation having a wavelength in a range from about 130 nm to about 400 nm, which is considered OOB radiation for EUV lithography. In some embodiments, the radiation-absorption control group R2 contains C5-C20 benzene, naphthalene, phenanthrene, or pentacenequinone derivatives. In some embodiments, the ratio (or concentration) of the radiation-absorption control group R2 is between about 0% and about 50% in the additive 80. In other words, about 0%-50% of the additive 80 is the radiation-absorption control group R2.

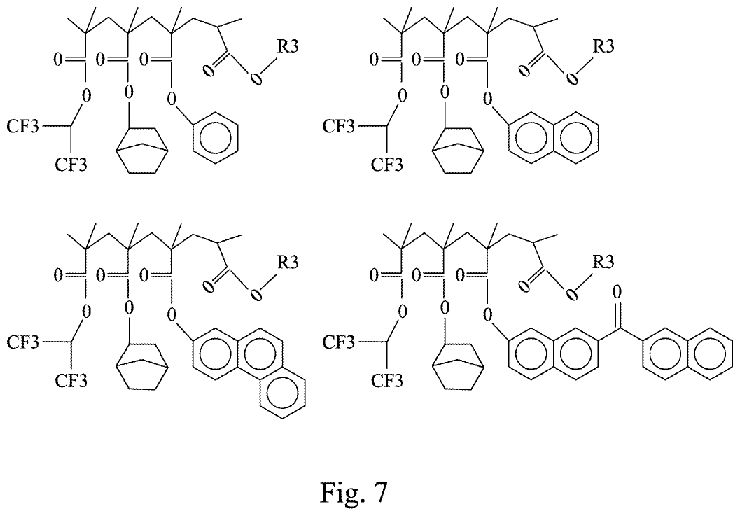

With reference to FIG. 7, in some embodiments, an additive in accordance with embodiments of the present disclosure including a developer solubility group R3 in combination with a floating control group Rf, a volume control group R1 and a radiation-absorption control group R2 has one of the following chemical formulas. In the embodiments of FIG. 7, the chemical formulas for the floating control group Rf and the volume control group R1 are the same. FIG. 7 illustrates different examples of chemical formulas for the radiation-absorption control group R2 where A3=COO— which serves as a link between the radiation-absorption control group R2 and the backbone of the additive polymer.

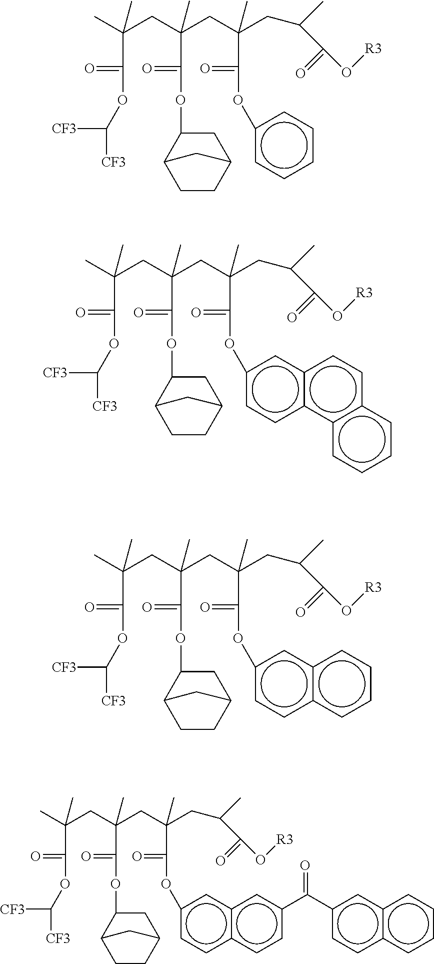

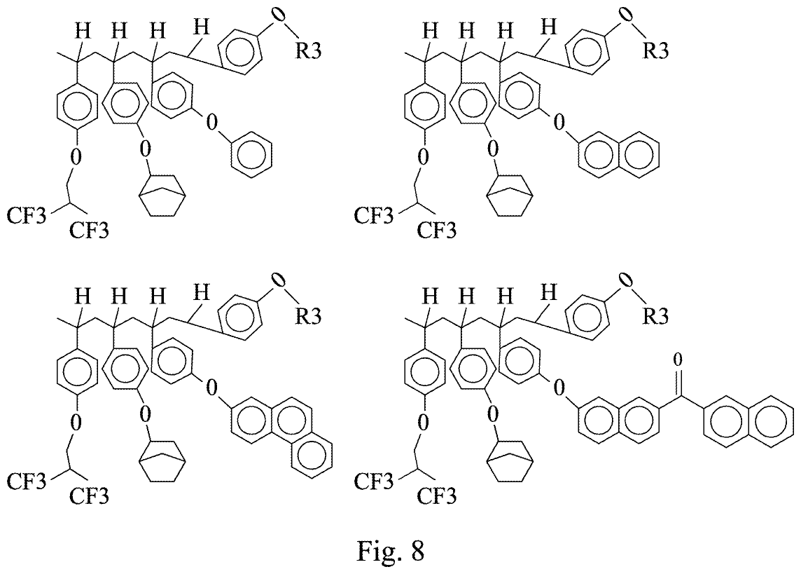

With reference to FIG. 8, in some embodiments, an additive in accordance with embodiments of the present disclosure including a developer solubility group R3 in combination with a floating control group Rf, a volume control group R1 and a radiation-absorption control group R2 has one of the following chemical formulas. In the embodiments of FIG. 8, the chemical formulas for the floating control group Rf and the volume control group R1 are the same. FIG. 8 illustrates different examples of chemical formulas for the radiation-absorption control group R2 where A3=phenyl-O— which serves as a link between the radiation-absorption control group R2 and the backbone of the additive polymer.

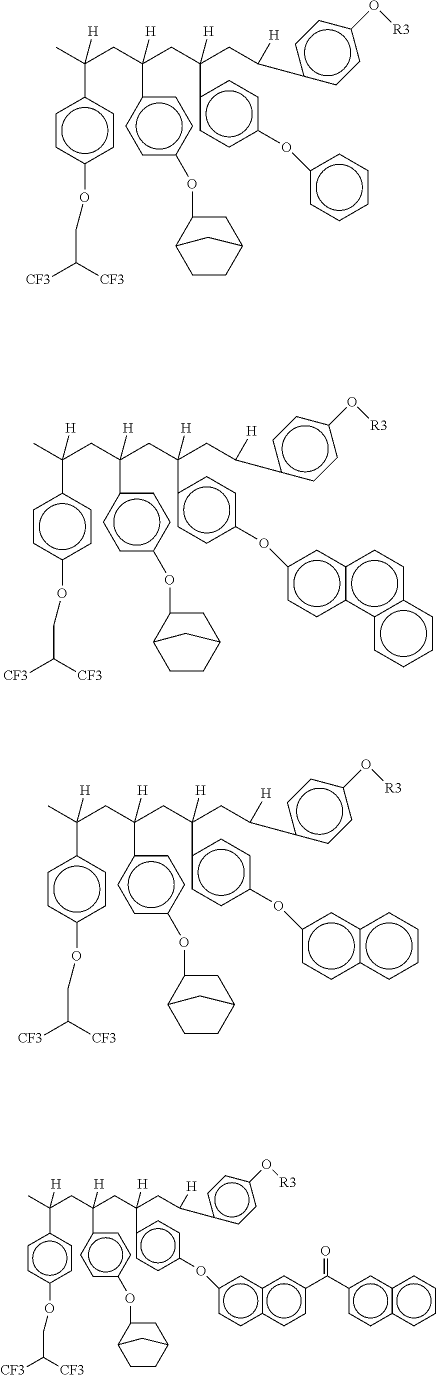

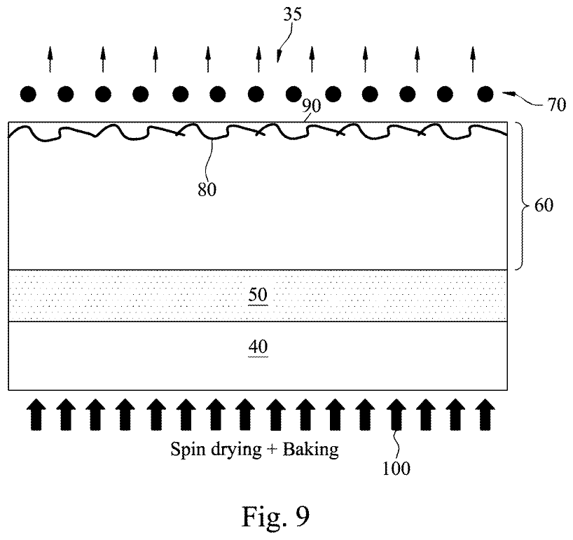

Referring now to FIG. 9, a spin drying and baking process 100 is performed on the semiconductor device 35. It is understood that in some embodiments, the process 100 may include two distinct steps: a step of spin drying, and a subsequent step of baking. For reasons of simplicity, however, the two steps are not separately illustrated herein. In the spin drying step, the substrate 40 and the layers formed thereon (including the photoresist material 60) are spin-dried. During the spin drying process, the additive 80 floats or rises toward the upper surface 90 of the photoresist material 60. This is due to the properties of the floating control group Rf of the additive 80 discussed above. During the baking step, the solvent 70 has evaporated out of the photoresist material 60, and the additive 80 has risen to the upper surface 90 of the photoresist material 60.

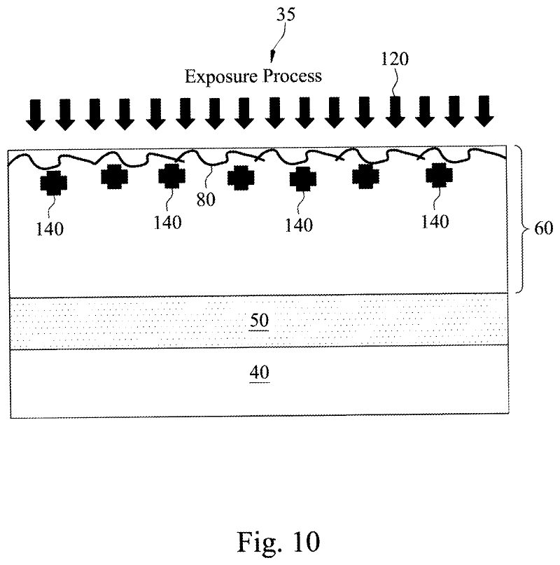

The floating additive 80 effectively forms a protective layer at or near the upper surface 90 of the photoresist material 60. Due to the properties of the volume control group of the additive 80 discussed above, the additive 80 can sufficiently block photoresist outgassing products. For example, referring now to FIG. 10, an exposure process 120 (which may include a post-exposure baking (PEB) step) is performed to the photoresist material 60 as a part of the EUV lithography process. The EUV lithography process may use a light source (or illumination source) that has a wavelength less than about 250 nm, for example about 13.5 nm. In some embodiments, the illumination source has at least one of: KrF, ArF, EUV, or E-beam. The light source exposes a predetermined region of the photoresist material 60, while other regions of the photoresist material 60 are protected through the use of a photomask (not illustrated).

The exposure process 120 (either the exposure itself or the PEB, or both) leads to the generation of various photoresist outgassing products 140, which as discussed above may be caused by PAG products, decomposition products from the PAG, or photochemical cleavage of protecting groups, among other things. The additive 80 is voluminous and dense enough so that the photoresist outgassing products 140 are trapped by the protective layer formed by the additive 80 (e.g., underneath the additive 80). As such, the outgassing products 140 cannot escape from the photoresist material 60, which reduces contamination of lithography equipment and improves lithography performance.

It is understood that this protective layer formed by the additive 80 is still within the photoresist material 60. As such, it does not add to the height of the photoresist material and will not adversely affect the aspect ratio of any subsequently formed photoresist patterns. In this manner, the present application is free of the issues that are associated with forming a separate top coating over the photoresist to prevent outgassing.

After the exposure process 120 is performed, subsequent lithography processes (e.g., developing, rinsing, etc.) may be performed to form a patterned photoresist (not illustrated herein for reasons of simplicity). Using the patterned photoresist as a mask, additional fabrication processes such as etching or implantation may be performed. Thereafter, the patterned photoresist may be removed by a photoresist removal process known in the art, such as a stripping or an ashing process.

Upon contact with a developing solution having a greater than about 9 or 10 pH, the developer solubility group R3 in the additive 80 contained in the photoresist material 60 undergoes a ring opening reaction discussed above producing terminal hydroxyl and carboxylic acid groups. Such terminal hydroxyl and carboxylic acid groups increases the hydrophilicity of the photoresist material number 60, thus rendering the photoresist material more soluble in the developing solution. Enhancing the solubility of the photoresist material in the developer solution results in improved pattern transfer to the photoresist and ultimately the workpiece. In addition, the LWR and LCDU are positively impacted when the photoresist has enhanced solubility in the developer solution.

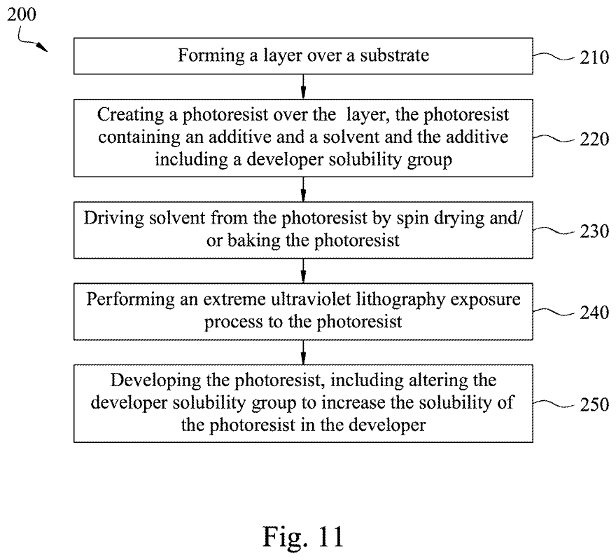

FIG. 11 is a flowchart of a method 200 of forming a semiconductor pattern according to various aspects of the present disclosure. The method 200 may be performed as a part of a lithography process, for example as a part of an extreme ultraviolet (EUV) lithography process in some embodiments.

The method 200 includes a step 210 of forming a layer over a substrate. In some embodiments, the substrate is substantially conductive or semi-conductive. The electrical resistance may be less than about 10³ ohm-meter. In some embodiments, the substrate contains metal, metal alloy, or metal nitride/sulfide/selenide/oxide/silicide with the formula MXₐ, where M is a metal, and X is N, S, Se, O, Si, and where “a” is in a range from about 0.4 to 2.5. For example, the substrate 40 may contain Ti, Al, Co, Ru, TiN, WN₂, or TaN. In some other embodiments, the substrate contains a dielectric material with a dielectric constant in a range from about 1 to about 40. In some other embodiments, the substrate contains Si, metal oxide, or metal nitride, where the formula is MX_{b}, wherein M is a metal or Si, and X is N or O, and wherein “b” is in a range from about 0.4 to 2.5. For example, the substrate may contain SiO₂, silicon nitride, aluminum oxide, hafnium oxide, or lanthanum oxide.

The layer formed over the substrate has different optical properties than photoresist. For example, the layer has a different n, k, or T value from photoresist. In some embodiments, the layer comprises at least one of different polymer structure, acid labile molecule, PAG (photo acid generator) loading, quencher loading, chromophore, cross linker, or solvent, which lead to different n value to photoresist. In some embodiments, the layer and photoresist have different etching resistance. In some embodiments, the layer contains an etching resistant molecule. The molecule includes an onium salt, a double bond, triple bond, silicon, silicon nitride, Ti, TiN, Al, aluminum oxide, SiON, or combinations thereof.

The method 200 includes a step 220 of coating a photoresist over the layer. The photoresist contains an additive. In some embodiments, the additive contains a developer solubility control group R3 which increases the solubility of the developed photoresist in the developing solution as described above.

In some embodiments, at step 220, the additive includes a floating control group configured to cause the additive to float toward the upper surface of the photoresist, as well as a volume control group configured to block photoresist outgassing products. In some embodiments, the floating control group contains fluorine or C1-C9 fluorine-containing alkyl group. In some embodiments, the volume control group contains C5-C20 alkyl group, cycloalkyl group, hydroxylalkyl group, alkoxy group, alkoxyl alkyl group, acetyl group, acetylalkyl group, carboxyl group, alky carboxyl group, cycloalkyl carboxyl group, C5-C20 saturated or unsaturated hydrocarbon ring, or C5-C20 heterocyclic group.

In some embodiments, the additive further contains a radiation-absorption control group configured to absorb radiation having a wavelength in a range from about 130 nanometers to about 400 nanometers. In some embodiments, the radiation-absorption control group contains C5-C20 benzene, naphthalene, phenanthrene, or pentacenequinone derivatives.

The method 200 includes a step 230 of spin drying or baking the photoresist. The additive floats to an upper surface of the photoresist during the spin drying or the baking of the photoresist, thereby forming a protective layer at the upper surface of the photoresist.

The method 200 includes a step 240 of performing an exposure process to the photoresist, thereby producing one or more photoresist outgassing products. The exposure process may be performed as a part of an EUV lithography process and may include an exposure step and a post-exposure bake (PEB) step. The photoresist outgassing products may be produced during the exposure step and/or the PEB step. The additive floating at the upper surface of the photoresist prevents the one or more photoresist outgassing products from escaping the photoresist.

The method 200 includes a step 250 of developing the exposed photoresist. Developing of the exposed photoresist includes exposing the exposed photoresist to a developing solution capable of dissolving portions of the photoresist exposed to the EUV radiation (positive photoresist) or dissolving portions of the photoresist that have not been exposed to the EUV radiation (negative photoresist). Examples of a developer solution include trimethyl ammonium hydroxide (TMAH). TMAH developing solutions have a pH of about 9 or greater or about 10 or greater. Exposing the developer solubility group R3 that includes a heterocyclic ring which is capable of undergoing a ring opening reaction at elevated pH, e.g., on the order of greater than pH 9 or pH 10, to a developer solution at a pH of 9 or greater or 10 or greater promotes ring opening of the heterocyclic ring. When a developer like developer solubility group R3 undergoes a ring opening reaction, terminal hydroxyl groups and carboxylic acid groups are produced. These terminal hydroxyl groups and carboxylic acid groups increase the solubility of the photoresist in the TMAH. Increasing the solubility of the photoresist improves the ability of the developer solution to remove portions of the photoresist.

It is understood that additional processes may be performed before, during, or after the steps 210-250 of the method 200 to complete the fabrication of the semiconductor device. For example, the method 200 may include additional processes to pattern the photoresist, and then using the patterned photoresist as a mask for subsequent etching or ion implantation processes. As another example, the exposure process discussed herein may be done using a radiation having a first wavelength, and the photoresist may later be exposed by a radiation having a second wavelength (e.g., as a part of a double patterning process). For reasons of simplicity, these additional steps are not discussed herein in detail.

Based on the above discussions, it can be seen that the present disclosure offers advantages over conventional methods. It is understood, however, that other embodiments may offer additional advantages, and not all advantages are necessarily disclosed herein, and that no particular advantage is required for all embodiments. One advantage is that the photoresist additive herein can effectively increase the solubility of the photoresist containing additives in accordance with embodiments described herein. In addition, in some embodiments, the additives reduce photoresist outgassing. In more detail, the developer solubility group of the additive is capable of a ring opening reaction when elevated pH is encountered, such as when the photoresist is exposed to a developer solution including TMAH. The ring opening reaction of the developer solubility group generates hydroxyl and carboxylic acid groups which improve the solubility of the additive and photoresist containing the additive in the developer solution. In accordance with other embodiments, the floating control group of the additive allows the additive to float to the top surface of the photoresist during the spin drying and/or baking process. The volume control group of the additive is sufficiently dense and voluminous so as to serve as a barrier for the photoresist outgassing products produced during a subsequent exposure process for EUV lithography. In other words, the photoresist outgassing products generated by EUV exposure will be trapped underneath the photoresist additive that floats at the top surface of the photoresist. Since the photoresist outgassing products are substantially trapped within the photoresist itself, the lithography tools will not be contaminated (photoresist outgassing products can contaminate lithography tools), and lithography performance will also be improved.

Another advantage is that the various aspects of the present disclosure can be implemented without increasing fabrication costs. The benefits of the additives in accordance with embodiments of the present disclosure are achieved without the need to form a top coating of an additional material external to the photoresist. In addition, the use of the photoresist additive does not require additional or separate fabrication processes. Instead, the benefits of additives formed in accordance with the present disclosure will be obtained utilizing standard fabrication process flow, and thus not increase fabrication costs in terms of fabrication equipment or fabrication processing time.

Yet another advantage is that since the top coating herein is formed “inside” the photoresist itself (at or near its top surface), it does not increase the height of the photoresist. This is beneficial since an increased photoresist height would increase an aspect ratio and may lead to a worse process window and/or cause the patterned photoresist to collapse. In comparison, the photoresist containing additives described herein has the same height as conventional photoresist without the additive. Therefore, there are no concerns regarding a worse processing window or photoresist collapsing.

One more advantage is that the additive herein can be optionally configured to absorb out-of-band (OOB) radiation in EUV. OOB radiation leads to degraded semiconductor lithography performance and is therefore undesirable. Here, the radiation-absorption control group can absorb such OOB radiation, and as a result improve EUV lithography performance.

One aspect of this description relates to a method of fabricating a semiconductor device that includes forming a layer over a substrate. The layer is coated with the photoresist containing an additive that includes a developer solubility group. Solvent is driven from the photoresist prior to performing an extreme ultraviolet lithography exposure process to the photoresist. Subsequent to the EUV lithography exposure process, the photoresist is developed. The development of the photoresist includes altering the developer solubility group to increase the solubility of the photoresist in a developer solution.

Another aspect of this description relates to a method of fabricating a semiconductor device that includes forming a patternable layer over a substrate and thereafter forming a photosensitive layer over the patternable layer. The photosensitive layer contains an additive and a solvent where the additive includes at least a floating control group, a volume control group, a radiation absorbing group and a developer solubility group. The photosensitive layer is spin dried and baked to drive solvent from the photosensitive layer. After the baking, the photosensitive layer is exposed to EUV radiation. The exposed photosensitive layer is then developed. Developing of the exposed photosensitive layer includes altering the developer solubility group to include a terminal hydroxyl group that is a terminal carboxylic acid group.

Another aspect of this description relates to a photoresist that includes a solvent and an additive that includes a polymer. The polymer including a developer solubility group including a heterocyclic group capable of undergoing a ring opening reaction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device, comprising:
forming a layer over a substrate;
coating a photoresist over the layer, wherein the photoresist contains an additive and a solvent, wherein the additive includes a developer solubility group (R3);
performing an extreme ultraviolet (EUV) lithography exposure process to the photoresist; and
developing the photoresist after the performing of the exposure process, the developing including altering the developer solubility group of the photoresist in the developer.

2. The method of claim 1, wherein the developer solubility group comprises a heterocyclic group capable of undergoing a ring opening reaction.

3. The method of claim 2, where the heterocyclic group is a cyclic ester group.

4. The method of claim 3, wherein the cyclic ester group is a 5-10 membered substituted or unsubstituted lactone ring.

5. The method of claim 4, wherein the 5-10 membered substituted or unsubstituted lactone ring is a 5-10 membered lactone ring substituted with alkyl groups, hydroxy groups, alkyloxy groups, cyano group, amino groups, and aromatic groups.

6. The method of claim 2, wherein the developing the photoresist includes exposing the photoresist to a developing solution having a pH 9 or greater than 9.

7. The method of claim 1, wherein the additive further comprises a floating control group including fluorine or a C1-C9 fluorine-containing alkyl group.

8. The method of claim 1, wherein the additive further comprises a volume control group including a C5-C20 alkyl group, a cycloalkyl group, a hydroxylalkyl group, an alkoxy group, an alkoxyl alkyl group, an acetyl group, an acetylalkyl group, a carboxyl group, an alky carboxyl group, a cycloalkyl carboxyl group, a C5-C20 saturated or unsaturated hydrocarbon ring, or a C5-C20 heterocyclic group.

9. The method of claim 1, wherein the additive further comprises a radiation-absorption control group, wherein the radiation-absorption control group absorbs radiation having a wavelength in a range from about 130 nanometers to about 400 nanometers during the exposure process.

10. The method of claim 9, wherein the radiation-absorption control group comprises C5-C20 benzene, naphthalene, phenanthrene, or pentacenequinone derivatives.

11. The method of claim 1, further comprising driving the solvent from the photoresist by spin drying the photoresist and floating the additive to an upper surface of the photoresist during the spin drying.

12. The method of claim 1, wherein the altering the developer solubility group further includes altering the developer solubility group to have a terminal hydroxyl group and a terminal carboxylic acid.

13. A method of fabricating a semiconductor device, comprising:
forming a patternable layer over a substrate;
forming a photo-sensitive layer over the patternable layer, wherein the photo-sensitive layer contains an additive and a solvent, wherein the additive includes at least a floating control group (Rf), a volume control group (R1), a radiation-absorption control group (R2) and a developer solubility group (R3);
spin drying the photo-sensitive layer;
baking the photo-sensitive layer after the spin drying;
exposing, after the baking and as a part of an extreme ultraviolet (EUV) lithography process, the photo-sensitive layer to EUV radiation; and
developing the photo-sensitive layer after the exposing, the developing including altering the developer solubility group to include a terminal hydroxyl group and a terminal carboxylic acid group.

14. The method of claim 13, wherein the developer solubility group comprises a heterocyclic group capable of undergoing a ring opening reaction.

15. The method of claim 13, wherein the developer solubility group has one of the following chemical formulas: 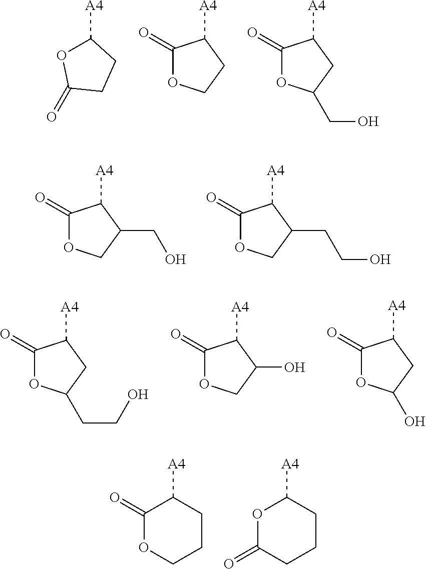
where A4 is —COO— or -phenyl-O.

16. The method of claim 13, wherein the floating control group comprises fluorine or C1-C9 fluorine-containing alkyl group.

17. The method of claim 13, wherein the volume control group comprises a C5-C20 alkyl group, a cycloalkyl group, hydroxylalkyl group, an alkoxy group, an alkoxyl alkyl group, an acetyl group, an acetylalkyl group, a carboxyl group, an alky carboxyl group, a cycloalkyl carboxyl group, a C5-C20 saturated or unsaturated hydrocarbon ring, or a C5-C20 heterocyclic group.

18. The method of claim 13, wherein the radiation-absorption control group comprises a C5-C20 benzene, naphthalene, phenanthrene, or pentacenequinone derivatives.

19. A photoresist comprising:
a solvent; and
an additive that includes a polymer, wherein the polymer includes a developer solubility group (R3) comprising a heterocyclic group capable of undergoing a ring opening reaction.

20. The photoresist of claim 19, wherein developer solubility group has one of the following chemical formulas: 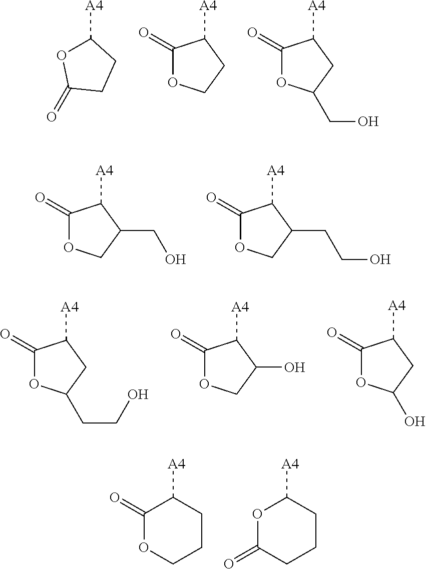
where A4 is —COO— or -phenyl-O.
